(19) United States
(12) Patent Application Publication
(10) Pub. No.: US 2022/0223696 A1
(43) Pub. Date: Jul. 14, 2022

(54) METHOD FOR MANUFACTURING POWER SEMICONDUCTOR DEVICE

(71) Applicant: ELECTRONICS AND TELECOMMUNICATIONS RESEARCH INSTITUTE, Daejeon (KR)

(72) Inventors: Jae Kyoung MUN, Daejeon (KR); Woojin CHANG, Daejeon (KR); Yoo Jin JANG, Daejeon (KR); Kyu Jun CHO, Daejeon (KR)

(73) Assignee: ELECTRONICS AND TELECOMMUNICATIONS RESEARCH INSTITUTE, Daejeon (KR)

(21) Appl. No.: 17/574,271

(22) Filed: Jan. 12, 2022

(30) Foreign Application Priority Data
Jan. 13, 2021 (KR) 10-2021-0004547
Nov. 24, 2021 (KR) 10-2021-0163365

(51) Int. Cl. H01L 29/40; H01L 21/02

(52) U.S. Cl. CPC H01L 29/401; H01L 21/02532; H01L 21/02178; H01L 21/02181; H01L 21/0228; H01L 21/02639; H01L 21/02535

(57) ABSTRACT

Disclosed is a method for manufacturing a power semiconductor device. The method includes forming a lower active layer on a substrate, forming an upper active layer on both sides of the lower active layer, forming a source electrode, a drain electrode, and a gate electrode on the upper active layer and the lower active layer, and forming a heat dissipating and electrical ground electrode penetrating the substrate and the lower active layer and connected to a lower surface of the lower active layer. The upper active layer may be epitaxially grown at a high doping concentration by a selective deposition method using a mask layer that exposes a portion of the lower active layer as a blocking layer.

### CROSS-REFERENCE TO RELATED APPLICATIONS

This U.S. non-provisional patent application claims priority under 35 U.S.C. § 119 of Korean Patent Application Nos. 10-2021-0004547, filed on Jan. 13, 2021, and 10-2021-0163365, filed on Nov. 24, 2021, the entire contents of which are hereby incorporated by reference.

### BACKGROUND

The present disclosure herein relates to a method for manufacturing a semiconductor device, and more particularly, to a method for manufacturing a power semiconductor device.

In general, power semiconductor devices may convert and control high-voltage power. Power semiconductor devices may have high-voltage resistance and high efficiency characteristics so as to be used in power transmission/distribution, home appliances, industries, transporters, etc.

With the development of next-generation power devices and power integrated circuits, the efficiency and power density of power electronics systems are remarkably improved. However, power semiconductor devices may have improvement requirements such as high operating voltage, high current density, high switching speed, low energy loss, etc. Power semiconductor devices may include wide bandgap semiconductor materials such as silicon (Si), silicon carbide (SiC), gallium nitride (GaN), or the like. Furthermore, power semiconductor devices may further include ultra-wide bandgap semiconductor materials such as gallium oxide (Ga₂O₃) or diamond.

### SUMMARY

The present disclosure provides a method for manufacturing a power semiconductor device capable of reducing an ohmic resistance between electrodes and an active layer.

Disclosed is a method for manufacturing a power semiconductor device. The method includes forming a lower active layer on a substrate, forming an upper active layer on both sides of the lower active layer, forming a source electrode, a drain electrode, and a gate electrode on the upper active layer and the lower active layer, and forming a ground electrode penetrating the substrate and the lower active layer and connected to a lower surface of the lower active layer. Here, the upper active layer may be epitaxially grown by a selective deposition method using a mask layer that exposes a portion of the lower active layer as a blocking layer.

In an embodiment, the forming of the upper active layer may include: forming the mask layer on a center of the lower active layer; depositing the upper active layer on the both sides of the lower active layer exposed from the mask layer; and removing a portion of the upper active layer.

In an embodiment, the forming of the upper active layer may further include forming a gate insulating layer on the lower active layer.

In an embodiment, the gate insulating layer may be formed on a portion of the upper active layer.

In an embodiment, the gate insulating layer may be formed between the lower active layer and the mask layer.

In an embodiment, the gate insulating layer may include an aluminum oxide (Al₂O₃) or hafnium oxide (HfO₂) formed using an atomic layer deposition (ALD) method.

In an embodiment, the mask layer may include a silicon oxide (SiO₂) or silicon nitride (SiNx) formed using a PECVD method.

In an embodiment, each of the lower active layer and the upper active layer may include an alpha gallium oxide (α-Ga₂O₃) formed through a mist-CVD process, an MBE process, or a HVPE process.

In an embodiment, the upper active layer may contain tin (Sn) or silicon (Si).

In an embodiment, the tin or silicon has a doping concentration of about 1×10¹⁹ to about 5×10¹⁹ EA/cm³.

In an embodiment, the substrate may include a sapphire.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a flowchart illustrating a method for manufacturing a power semiconductor device according to an embodiment of the inventive concept;

FIGS. 2 to 8 are cross-sectional views illustrating a manufacturing process of a power semiconductor device formed using the method of FIG. 1;

FIG. 9 is a flowchart illustrating an example of forming the upper active layer of FIG. 6;

FIG. 10 is a graph showing examples of a first current-voltage characteristic of a power semiconductor device according to an embodiment of the inventive concept and a second current-voltage characteristic of a typical semiconductor device;

FIG. 11 illustrates an example of forming the upper active layer of FIG. 6; and

FIGS. 12 to 17 are cross sectional views illustrating a manufacturing process of a power semiconductor device according to an embodiment of the inventive concept.

### DETAILED DESCRIPTION

Embodiments of the inventive concept will now be described in detail with reference to the accompanying drawings. The advantages and features of embodiments of the inventive concept, and methods for achieving the advantages and features will be apparent from the embodiments described in detail below with reference to the accompanying drawings. However, the inventive concept may be embodied in different forms and should not be construed as limited to the embodiments set forth herein. Rather, these embodiments are provided so that this disclosure will be thorough and complete, and will fully convey the scope of the inventive concept to those skilled in the art, and the inventive concept is only defined by the scope of the claims. Like reference numerals refer to like elements throughout.

The terminology used herein is not for delimiting the embodiments of the inventive concept but for describing the embodiments of the inventive concept. The terms of a singular form may include plural forms unless otherwise specified. It will be further understood that the terms “include”, “including”, “comprise”, and/or “comprising” used herein specify the presence of stated elements, steps, operations, and/or devices, but do not preclude the presence or addition of one or more other elements, steps, operations, and/or devices. Furthermore, the terms “active layer”, “source electrode”, “gate electrode”, and “drain electrode” used herein may be construed as meaning those commonly used in the field of semiconductors. Reference numerals, which are presented in the order of description, are provided according to the embodiments and are thus not necessarily limited to the order.

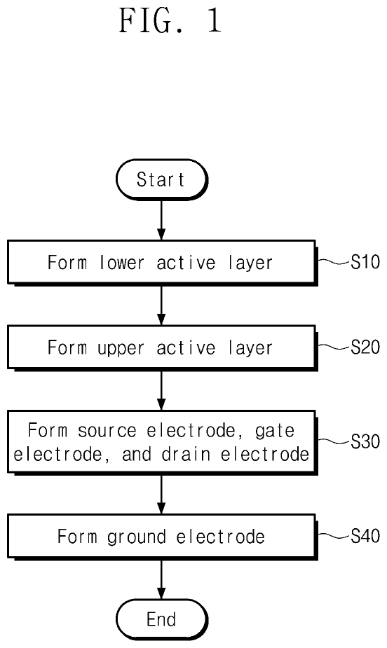

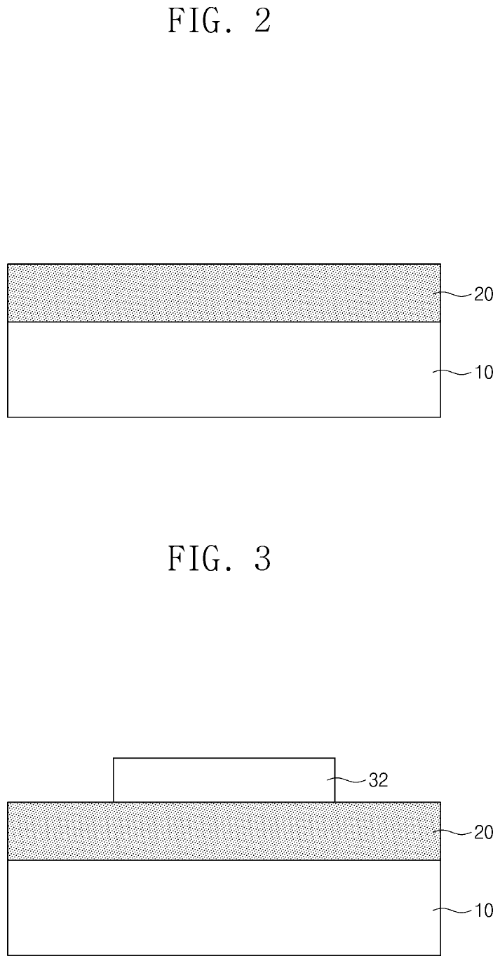

FIG. 1 illustrates a method for manufacturing a power semiconductor device according to an embodiment of the inventive concept. FIGS. 2 to 8 are cross-sectional views illustrating a manufacturing process of a power semiconductor device formed using the method of FIG. 1.

Referring to FIGS. 1 and 2, a lower active layer 20 is formed on a substrate 10 (S10). The lower active layer 20 having high performance may be formed without a lattice defect using a lattice mismatch of the substrate 10. For example, the substrate 10 may include a sapphire.

The lower active layer 20 may include an alpha gallium oxide (α-Ga₂O₃) formed using an epitaxial growing method of a molecule beam epitaxy (MBE), hydride vapor phase epitaxy (HVPE), metal organic chemical vapor deposition (MOCVD), or mist-CVD process. The MBE process may be performed using a process gas of ozone or oxygen radical. The HVPE process may higher productivity than the MBE process. The lower active layer 20 may contain impurities. The alpha gallium oxide (α-Ga₂O₃) may have a smaller lattice constant than a lattice constant of a beta gallium oxide (β-Ga₂₀₃), and may have a higher adhesive strength for the substrate 10 than the beta gallium oxide (β-Ga₂₀₃). The active layer 20 may contain tin (Sn) or silicon (Si) having a doping density of about 4×10¹⁷ cm⁻³ to about 5×10¹⁸ cm⁻³. The lower active layer 20 may have a thickness of about 100 nm to about 300 nm.

Referring to FIGS. 1 and 3 to 6, an upper active layer 30 is formed on both sides of the lower active layer 20 (S20). The upper active layer 30 may include the same material as the lower active layer 20. For example, the upper active layer 30 may include an alpha gallium oxide (α-Ga₂O₃).

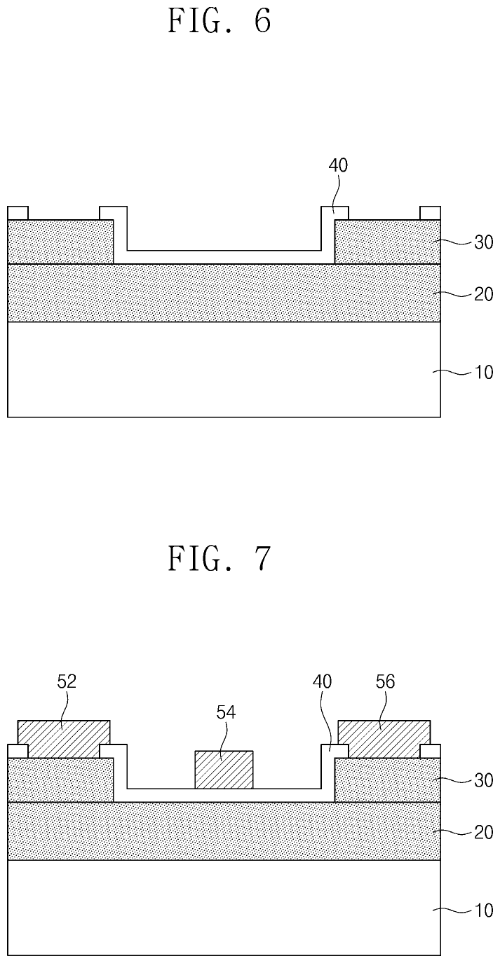

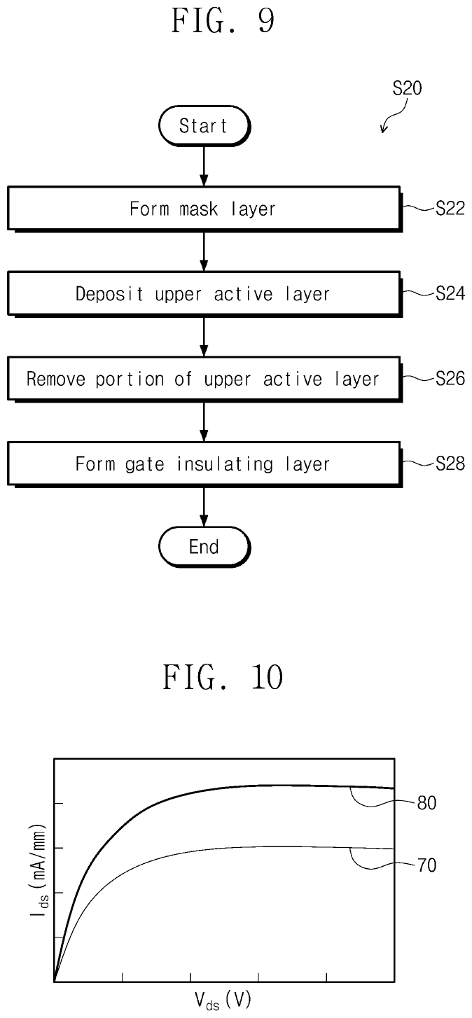

FIG. 9 illustrates an example of forming (S20) the upper active layer 30 of FIG. 6.

Referring to FIGS. 3 and 9, a mask layer 32 is formed on a center of the lower active layer 20 (S22). The mask layer 32 may include a silicon oxide (SiO₂) or silicon nitride (SiNx) formed using a plasma enhanced chemical vapor deposition (PECVD) method. The mask layer 32 may have a thickness of about 300 nm to about 500 nm. The mask layer 32 may be patterned through a lithography process and etching process. The lithography process may include a photolithography process or e-beam lithography process. The etching process may include an inductive coupled plasma reactive ion etching (ICP RIE) process. The mask layer 32 may expose both sides of the lower active layer 20.

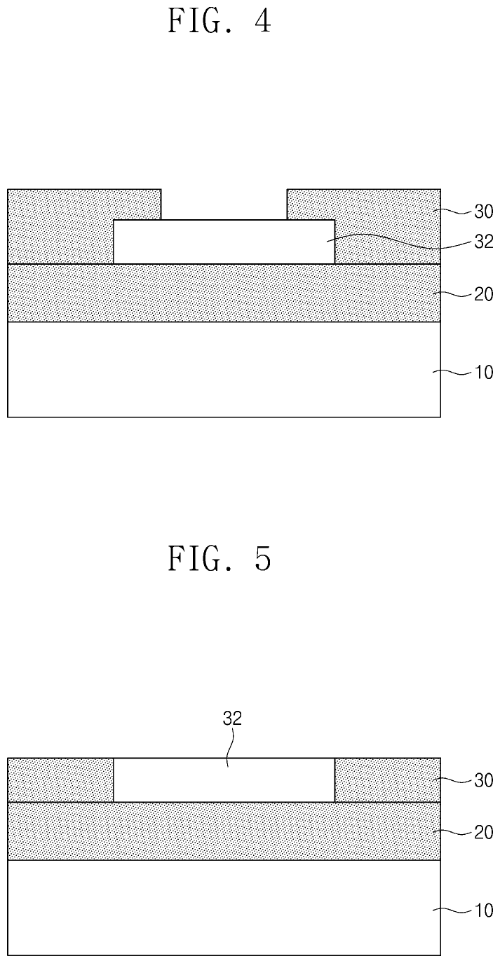

Referring to FIGS. 4 and 9, the upper active layer 30 is deposited on the both sides of the lower active layer 20 exposed from the mask layer 32 (S24).

The upper active layer 30 may include the same material as the lower active layer 20. For example, the upper active layer 30 may include an alpha gallium oxide (α-Ga₂O₃) formed using an epitaxial growing method of an MBE or HVPE process. According to an example, the upper active layer 30 may be epitaxially grown by a selective deposition method using the mask layer 32 as a blocking layer. The upper active layer 30 may have a thickness of about 10 nm to about 100 nm. The upper active layer 30 may contain a larger amount of impurities than the lower active layer 20. For example, the upper active layer 30 may contain tin (Sn) or silicon (Si) having a doping density of about 1×10¹⁹ cm⁻³ to about 5×10¹⁹ cm³.

Referring to FIGS. 5 and 9, a portion of the upper active layer 30 is removed (S26). The portion of the upper active layer 30 may be removed through an inductive coupled plasma reactive ion etching (ICP RIE) process. An etching gas for the ICP RIE process may include BCl₃ or Cl₂. An upper surface of the upper active layer 30 may be coplanar with an upper surface of the mask layer 32. Alternatively, the upper active layer 30 may be planarized through a chemical mechanical polishing process (CMP), but an embodiment of the inventive concept is not limited thereto. Thereafter, the mask layer 32 may be removed. The mask layer 32 may be removed through an ICP RIE process using SF₆ or CF₄ as an etching gas.

Referring to FIGS. 6 and 9, a gate insulating layer 40 is formed on the lower active layer 20 and a portion of the upper active layer 30 (S28). The gate insulating layer 40 may include a metal oxide formed using an atomic layer deposition method. For example, the gate insulating layer 40 may include aluminum oxide (Al₂O₃), hafnium oxide (HfO₂), strontium titanium oxide (SrTiO₃), or barium titanium oxide (BaTiO₃). The gate insulating layer 40 may have a thickness of about 10 nm to about 50 nm.

Referring to FIGS. 1 and 7, a source electrode 52, a gate electrode 54, and a drain electrode 56 are formed on the upper active layer 30 and the gate insulating layer 40 (S30). The source electrode 52, the gate electrode 54, and the drain electrode 56 may include metals of titanium (Ti), platinum (Pt), nickel (Ni), and gold (Au) formed using an e-beam deposition method. The metals of titanium (Ti), platinum (Pt), nickel (Ni), and gold (Au) may be patterned through a lithography process, a lift-off process, and an etching process. A multilayer structure of Ti/Au and Ti/Pt/Au may be provided for low-resistance heat treatment ohmic contact of the source and drain electrodes, and a structure of Ti/Au, Ti/Pt/Au Pt/Au, or Ni/Au may be provided for the gate electrode. Here, titanium (Ti) may increase adhesion to the upper active layer 30 or the gate insulating layer 40 as an ohmic contact forming and interface adhesive metal in the source electrode 52 and the drain electrode 56, and platinum (Pt) and nickel (Ni) may be only used as the gate electrode 54. Gold (Au) may be formed on titanium (Ti), nickel (Ni), and platinum (Pt) so as to function as a cap layer for improving electrical conductivity.

The source electrode 52 and the drain electrode 56 may be formed on the upper active layer 30, and the gate electrode 54 may be formed on the gate insulating layer 40. Each of the source electrode 52, the gate electrode 54, and the drain electrode 56 may have a thickness of about 20 nm to about 50 nm.

Alternatively, the source electrode 52 and the drain electrode 56 may be formed before the gate electrode 54 is formed. The source electrode 52 and the drain electrode 56 may have a laminate structure of titanium (Ti), platinum (Pt), and gold (Au). Platinum (Pt) may function as a diffusion barrier layer. The source electrode 52 and the drain electrode 56 may be heat treated. A heat treatment process of the source electrode 52 and the drain electrode 56 may include a rapid thermal annealing (RTA) process with an upper limit temperature of about 450° C. to about 600° C. The heat treatment process may be performed in an atmosphere of nitrogen (N₂). Thereafter, the gate electrode 54 may be formed on the gate insulating layer 40 between the source electrode 52 and the drain electrode 56. The gate electrode 54 may further include nickel (Ni) and gold (Au).

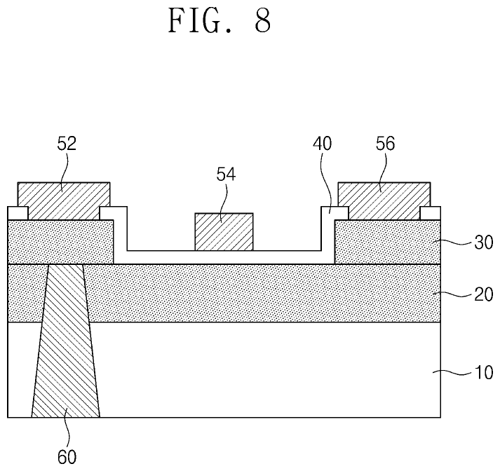

Referring to FIGS. 1 and 8, a ground electrode 60 contacting a lower surface of the upper active layer 30 is formed (S40). The ground electrode 60 may penetrate the substrate 10 and the lower active layer 20. A portion of the lower active layer 20 and substrate 10 may be removed through an ICP RIE process, thus forming a hole that exposes a portion of the lower surface of the upper active layer 30. The ground electrode 60 may be formed in the hole. The ground electrode 60 may include gold (Au) or copper (Cu) having high thermal conductivity. The substrate 10 may be thinned using a lapping or polishing method.

Although not illustrated, the substrate 10 and the lower active layer 20 may be separated using a laser lift-off method. For example, the substrate 10 may absorb ultraviolet laser light, and the lower active layer 20 may transmit the laser light. A boundary surface between the substrate 10 and the lower active layer 20 may be melted or decomposed, and the substrate 10 may be separated from the lower active layer 20. Thereafter, the lower active layer 20 may be bonded onto a heat dissipation substrate of metal, SiC, AlN, or diamond. The heat dissipation substrate may improve heat dissipation characteristics of the lower active layer 20.

FIG. 10 illustrates a first current-voltage characteristic 80 of the power semiconductor device according to an embodiment of the inventive concept and a second current-voltage characteristic 70 of a typical power semiconductor device.

Referring to FIGS. 8 and 10, the first current-voltage characteristic 80 of the power semiconductor device according to an embodiment of the inventive concept may be superior to the second current-voltage characteristic 70 of the typical power semiconductor device. For example, the power semiconductor device according to an embodiment of the inventive concept may have a higher current density than that of the typical power semiconductor device. The current density may be inversely proportional to an ohmic resistance between electrodes and an active layer. An upper active layer of the typical power semiconductor device may include an amorphous gallium oxide or poly gallium oxide. The upper active layer 30 including an alpha gallium oxide (α-Ga₂O₃) optionally doped with tin (Sn) or silicon (Si) ions at a concentration of about 1×10¹⁹ cm⁻³ to about 5×10¹⁹ cm⁻³ and epitaxially grown may reduce the ohmic resistance between the lower active layer 20 and the source electrode 52 and between the lower active layer 20 and the drain electrode 56.

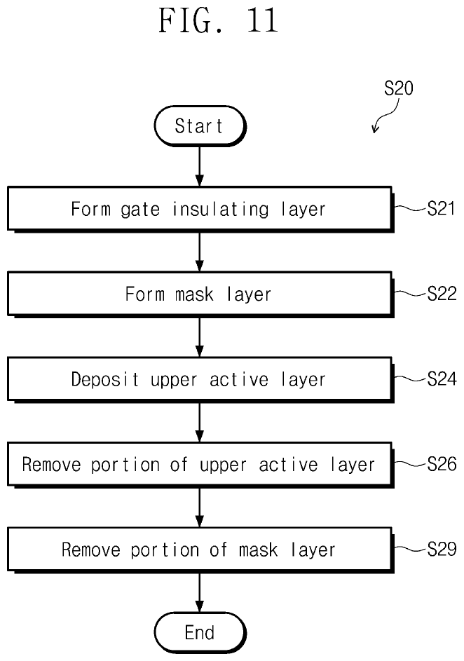

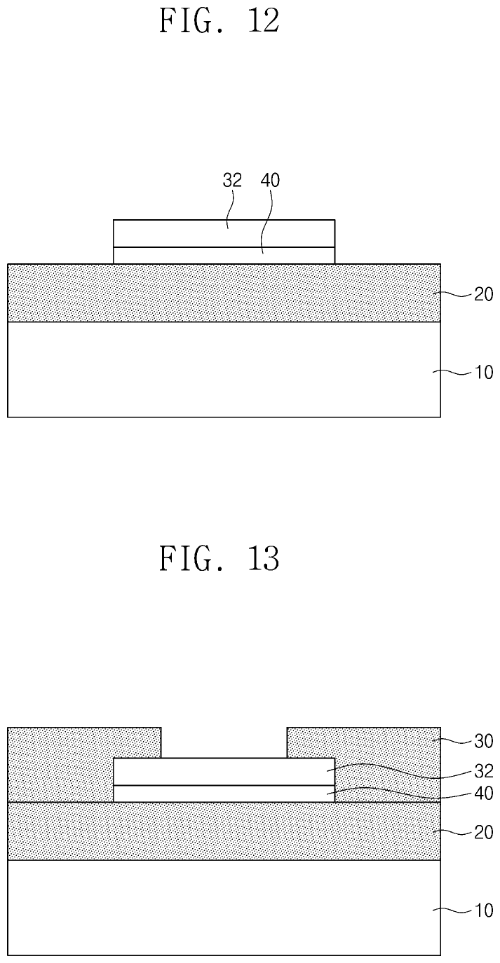

FIG. 11 illustrates an example of forming (S20) the upper active layer 30 of FIG. 6. FIGS. 12 to 17 are cross sectional views illustrating a manufacturing process of a power semiconductor device according to an embodiment of the inventive concept.

Referring to FIGS. 11 and 12, the gate insulating layer 40 is formed on the lower active layer 20 (S21). The gate insulating layer 40 may include a metal oxide formed using an atomic layer deposition method. The gate insulating layer 40 may be deposited over an upper surface of the substrate 10.

Next, the mask layer 32 is formed on the gate insulating layer 40 (S22). The mask layer 32 may include a silicon oxide (SiO₂) or silicon nitride (SiNx) formed using a PECVD method. Thereafter, the mask layer 32 and the gate insulating layer 40 may be patterned through a lithography process and an etching process, thus exposing both sides of the lower active layer 20.

Referring to FIGS. 11 and 13, the upper active layer 30 is deposited on the both sides of the lower active layer 20 exposed from the mask layer 32 and the gate insulating layer 40 (S24). The upper active layer 30 may be epitaxially grown by a selective deposition method using the mask layer 32 and the gate insulating layer 40 as a blocking layer.

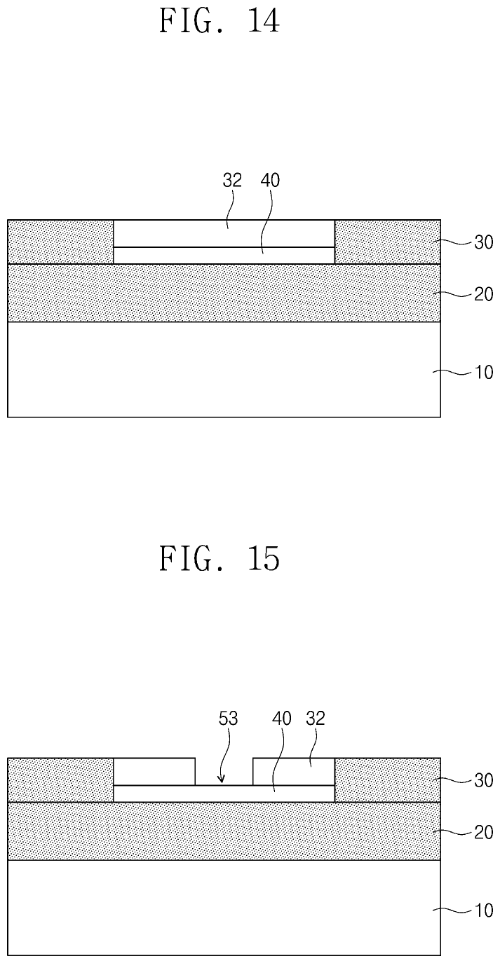

Referring to FIGS. 11 and 14, a portion of the upper active layer 30 is removed (S26).

Referring to FIGS. 11 and 15, a trench 53 is formed by removing a portion of the mask layer 32 (S29). The trench 53 may be formed through a lithography process and etching process of the mask layer 32. The etching process may include an ICP RIE process. The trench 53 may expose a portion of an upper surface of the gate insulating layer 40. The gate insulating layer 40 may be used as an etch stop layer during the ICP RIE process. The trench 53 may be formed on a center of the gate insulating layer 40.

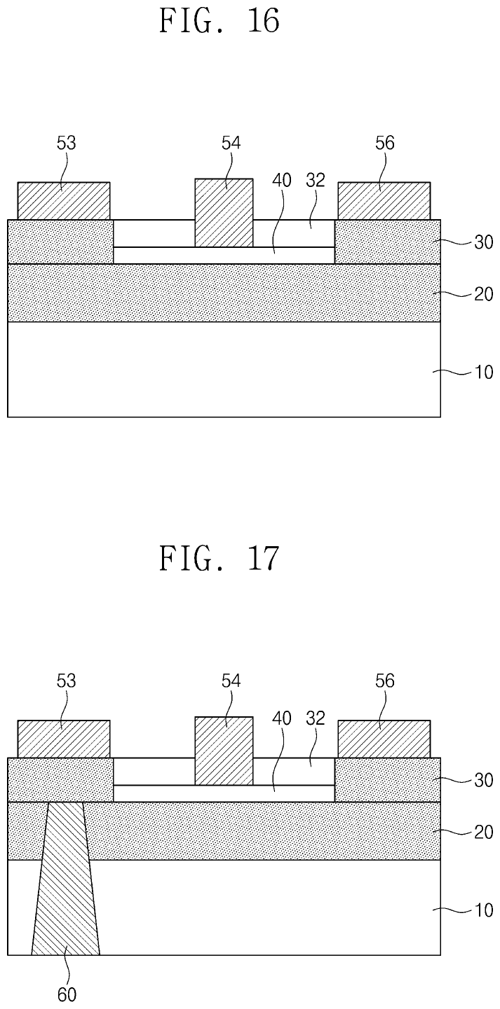

Referring to FIGS. 1 and 16, the source electrode 52 and the drain electrode 56 are formed on the upper active layer 30, and the gate electrode 54 is formed in the trench 53 (S30). The source electrode 52 and the drain electrode 56 may be formed before the gate electrode 54 is formed or at the same time when the gate electrode 54 is formed. However, an embodiment of the inventive concept is not limited thereto.

Referring to FIGS. 1 and 17, the ground electrode 60 penetrating the substrate 10 and the lower active layer 20 and contacting a lower surface of the upper active layer 30 is formed (S40). The ground electrode 60 may be formed through a lithography process, etching process, and metal deposition process of the substrate 10 and the lower active layer 20. A photoresist pattern (not shown) may be formed on a lower surface of the substrate 10 through a lithography process. A hole may be formed by removing a portion of the substrate 10 and lower active layer 20 through an ICP RIE process using the photoresist pattern as an etching mask. The ground electrode 60 may be formed in the hole.

As described above, the method for manufacturing a power semiconductor device according to an embodiment of the inventive concept may reduce the ohmic resistance between the lower active layer and the source electrode and between the lower active layer and the drain electrode using the upper active layer epitaxially grown on the lower active layer.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A method for manufacturing a power semiconductor device, the method comprising:
forming a lower active layer on a substrate;
forming an upper active layer on both sides of the lower active layer;
forming a source electrode, a drain electrode, and a gate electrode on the upper active layer and the lower active layer; and
forming a ground electrode penetrating the substrate and the lower active layer and connected to a lower surface of the lower active layer,
wherein the upper active layer is epitaxially grown by a selective deposition method using a mask layer that exposes a portion of the lower active layer as a blocking layer.

2. The method of claim 1, wherein the forming of the upper active layer comprises:
forming the mask layer on a center of the lower active layer;
depositing the upper active layer on the both sides of the lower active layer exposed from the mask layer; and
removing a portion of the upper active layer.

3. The method of claim 2, wherein the forming of the upper active layer further comprises forming a gate insulating layer on the lower active layer.

4. The method of claim 3, wherein the gate insulating layer is formed on a portion of the upper active layer.

5. The method of claim 3, wherein the gate insulating layer is formed between the lower active layer and the mask layer.

6. The method of claim 3, wherein the gate insulating layer includes an aluminum oxide or hafnium oxide formed using an atomic layer deposition method.

7. The method of claim 1, wherein the mask layer includes a silicon oxide or silicon nitride formed using a plasma enhanced chemical vapor deposition (PECVD) method.

8. The method of claim 1, wherein each of the lower active layer and the upper active layer includes an alpha gallium oxide (α-Ga₂O₃) formed through a mist chemical vapor deposition (mist-CVD) method, a molecule beam epitaxy (MBE) process, or a hydride vapor phase epitaxy (HVPE) process.

9. The method of claim 1, wherein the upper active layer contains tin or silicon.

10. The method of claim 9, wherein the tin or silicon has a doping concentration of 1×10¹⁹ EA/cm³ to 5×10¹⁹ EA/cm³.

11. The method of claim 1, wherein the substrate includes sapphire, silicon (Si), or silicon carbide (SiC).
